(19) United States
(12) Patent Application Publication
(10) Pub. No.: US 2009/0114899 A1
(43) Pub. Date: May 7, 2009

(54) RESISTANCE MEMORY AND METHOD FOR MANUFACTURING THE SAME

(75) Inventors: HENG-YUAN LEE, Tainan County (TW); CHING-CHIUN WANG, Miaoli County (TW); PANG-HSU CHEN, Hsinchu City (TW); TAI-YUAN WU, Taipei City (TW)

Correspondence Address: WPAT, PC, 7225 BEVERLY ST., ANNANDALE, VA, 22003, US

(73) Assignee: INDUSTRIAL TECHNOLOGY RESEARCH INSTITUTE, Hsinchu (TW)

(21) Appl. No.: 12/141,966

(22) Filed: Jun. 19, 2008

(30) Foreign Application Priority Data
Nov. 1, 2007 (TW) 096141126

(51) Int. Cl. H01L 47/00; H01L 21/8234

(52) U.S. Cl. 257/4; 438/275; 257/E29.169

(57) ABSTRACT

A resistance memory is manufactured using semiconductor processing to comprise planar dual-tip electrodes so that the electric field in the resistance memory is concentrated to reduce the number of fuses in the dielectric material and improve the device characteristics. The resistance memory comprises: a first memory cell including a first bottom electrode and a common top electrode; and a second memory cell including a second bottom electrode and the common top electrode shared with the first memory cell; wherein the first bottom electrode, the second bottom electrode and the common top electrode are disposed on the same plane and are separated by a resistive conversion layer; wherein the common top electrode is connected to the ground through a via, while the first bottom electrode and the second bottom electrode are connected to the source of a transistor through a plug, respectively.

### BACKGROUND OF THE INVENTION

1. Field of the Invention

The present invention generally relates to a resistance memory and a method for manufacturing the same and, more particularly, to a resistance memory with planar dual-tip electrodes and a method for manufacturing the resistance memory so that the electric field in the resistance memory is concentrated to reduce the number of fuses in the dielectric material and improve the device characteristics.

2. Description of the Prior Art

The resistance memory, for example the phase-change memory (PCM) and the oxide resistance memory, has a confined conductive region in the dielectric material, in which the current distribution can be control to modulate the resistance to improve the device characteristics such as the operation voltage and the operation current.

The characteristics of an oxide resistance memory strongly rely on the fuses formed in the confined conductive region in the dielectric material. Generally, the number and structure of fuses formed by applying high voltages are uncontrollable due to arbitrarily distributed defects, resulting in higher operation current and unreliable characteristics. Therefore, it is crucial to effectively control the number and structure of fuses to improve the characteristics of such a resistance memory.

FIG. 1 is a cross-sectional diagram of a resistance memory disclosed in U.S. Patent Pub. No. 2006/0027893 filed by IBM. In FIG. 1, a transistor layer 11 comprising a plurality of transistors and related circuits (not shown) is formed on a substrate 10. An insulating layer 12 is formed on the transistor layer 11. A bottom electrode 13 and a dielectric material 14 are sequentially formed in the insulating layer 12. A top electrode 15 is formed on the dielectric material 14 so that the bottom electrode 13, the dielectric material 14 and the top electrode 15 form a metal-insulator-metal (MIM) capacitor. More particularly, a downward protrusion 16 on the bottom surface of the top electrode 15 supports the generation of a concentrated electric field in the dielectric material 14. Therefore, the number of fuses formed in the confined conductive region in the dielectric material 14 can be reduced to improve the device characteristics. However, in this resistance memory, only the electric field near the protrusion 16 on the bottom surface of the top electrode 15 is concentrated while the electric field near the bottom electrode 13 is somewhat dispersed.

In order to overcome the above mentioned problems, there is need in providing a resistance memory manufactured using semiconductor processing to comprise planar dual-tip electrodes so that the electric field in the resistance memory is concentrated to reduce the number of fuses in the dielectric material and improve the device characteristics.

### SUMMARY OF THE INVENTION

It is an object of the present invention to provide a resistance memory manufactured using semiconductor processing to comprise planar dual-tip electrodes so that the electric field in the resistance memory is concentrated to reduce the number of fuses in the dielectric material and improve the device characteristics.

In order to achieve the foregoing object, the present invention provides a method for manufacturing a resistance memory, comprising steps of:
providing a semiconductor substrate comprising a plurality of transistors, whereon a first insulating layer comprising a plurality of first plugs so that each of the plurality of first plugs are connected to the source/drain of one the plurality of transistors;
forming a conducting layer on the first insulating layer so that the conducting layer is connected to the first plugs;
forming a second insulating layer comprising a plurality of second plugs on the first insulating layer and the conducting layer so that the second plugs are connected to the first plugs through the conducting layer;
forming an electrode layer and a sacrificial layer sequentially on the second insulating layer;
defining a patterned sacrificial layer by photo-lithography and etching so that the patterned sacrificial layer comprises two adjacent head-to-head semi-circular, semi-elliptic or semi-polygonal patterns to expose part of the electrode layer;
depositing on the electrode layer a thin film formed of a material that the sacrificial layer is formed of, the thin film being thick enough for the two adjacent head-to-head semi-circular, semi-elliptic or semi-polygonal patterns to joint;
anisotropically etching the thin film to form a sidewall;
depositing on the electrode layer a mask layer formed of another material different from the material that the sacrificial layer is formed of and planarizing the mask layer;
removing the patterned sacrificial layer and the sidewall while remaining the mask layer and exposing part of the electrode layer;
using the mask layer to remove the exposed part of electrode layer to expose part of the second insulating layer and removing the mask layer to form a planar dual-tip electrode structure;
forming a resistive conversion layer on the second insulating layer to cover the planar dual-tip electrode structure; and
forming a third insulating layer on the resistive conversion layer with a via to connect a common top electrode of the planar dual-tip electrode structure to the ground.

The present invention provides a resistance memory with a planar dual-tip electrode structure comprising:
a first memory cell comprising a first bottom electrode and a common top electrode; and
a second memory cell including a second bottom electrode and the common top electrode shared with the first memory cell;
wherein the first bottom electrode, the second bottom electrode and the common top electrode are disposed on the same plane and are separated by a resistive conversion layer.

### BRIEF DESCRIPTION OF THE DRAWINGS

The objects, spirits and advantages of the preferred embodiment of the present invention will be readily understood by the accompanying drawings and detailed descriptions, wherein:

FIG. 1 is a cross-sectional diagram of a conventional resistance memory;

FIG. 2 is a cross-sectional diagram showing a first step of a method for manufacturing a resistance memory according to the present invention;

FIG. 3 is a cross-sectional diagram showing a second step of a method for manufacturing a resistance memory according to the present invention;

FIG. 4 is a cross-sectional diagram showing a third step of a method for manufacturing a resistance memory according to the present invention;

FIG. 5 is a top-view diagram of the left half of FIG. 4;

FIG. 6A is a cross-sectional diagram showing a fourth step of a method for manufacturing a resistance memory according to one embodiment of the present invention;

FIG. 6B is a cross-sectional diagram showing a fourth step of a method for manufacturing a resistance memory according to another embodiment of the present invention;

FIG. 6C is a cross-sectional diagram showing a fourth step of a method for manufacturing a resistance memory according to still another embodiment of the present invention;

FIG. 7A is a cross-sectional diagram along the XX direction showing a fifth step of a method for manufacturing a resistance memory according to the present invention;

FIG. 7B is a cross-sectional diagram along the YY direction showing a fifth step of a method for manufacturing a resistance memory according to the present invention;

FIG. 8A is a top-view diagram showing a sixth step of a method for manufacturing a resistance memory according to the present invention;

FIG. 8B is a cross-sectional diagram along the XX direction showing a fifth step of a method for manufacturing a resistance memory according to the present invention;

FIG. 8C is a cross-sectional diagram along the YY direction showing a fifth step of a method for manufacturing a resistance memory according to the present invention;

FIG. 9A is a top-view diagram showing a seventh step of a method for manufacturing a resistance memory according to the present invention;

FIG. 9B is a cross-sectional diagram along the XX direction showing a seventh step of a method for manufacturing a resistance memory according to the present invention;

FIG. 10 is a top-view diagram showing an eighth step of a method for manufacturing a resistance memory according to the present invention;

FIG. 11A is a top-view diagram showing a ninth step of a method for manufacturing a resistance memory according to the present invention;

FIG. 11B is a cross-sectional diagram along the XX direction showing a ninth step of a method for manufacturing a resistance memory according to the present invention;

FIG. 12 is a cross-sectional diagram showing a tenth step of a method for manufacturing a resistance memory according to the present invention;

FIG. 13 is a cross-sectional diagram showing an eleventh step of a method for manufacturing a resistance memory according to the present invention; and

FIG. 14 is a 3-D structural diagram of planar dual-tip electrodes of a resistance memory according to the present invention.

### DETAILED DESCRIPTION OF THE PREFERRED EMBODIMENT

The present invention can be exemplified by the preferred embodiments as described hereinafter.

In the present invention, there is provided a resistance memory with planar dual-tip electrodes and a method for manufacturing the resistance memory so that the electric field in the resistance memory is concentrated to reduce the number of fuses in the dielectric material and improve the device characteristics.

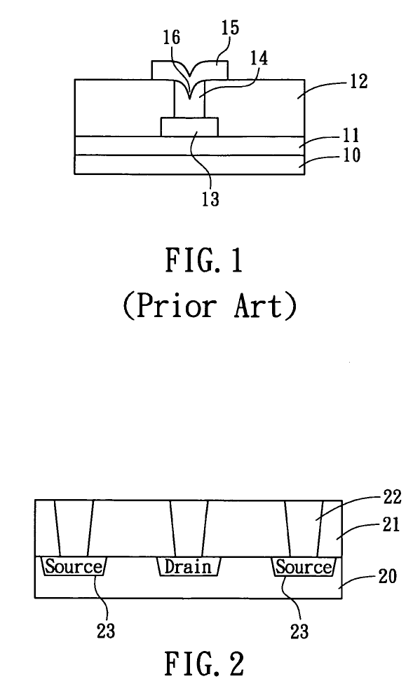

FIG. 1 to FIG. 11 are cross-sectional diagrams and related drawings showing the first step to the twelfth step of a method for manufacturing a resistance memory according to the present invention. First, FIG. 2 is a cross-sectional diagram showing a first step of a method for manufacturing a resistance memory according to the present invention. In FIG. 2, a semiconductor substrate 20 is provided to comprise a plurality of transistors (not shown). A first insulating layer 21 comprising a plurality of first plugs 22 is formed on the semiconductor substrate 20 so that each of the plurality of first plugs 22 are connected to the source/drain 23 of one the plurality of transistors. The technology of semiconductor processing for transistor manufacturing is well-known to those with ordinary skills in the art, and thus description thereof is not presented.

More particularly, after the first insulating layer 21 is formed, a plurality of openings are formed in the first insulating layer 21 by photo-lithography and etching. A conductive material is deposited to fill in the plurality of openings and then the conductive material is planarized to form the plurality of first plugs 22. The conductive material is implemented by tungsten (W) or other conductive metal materials.

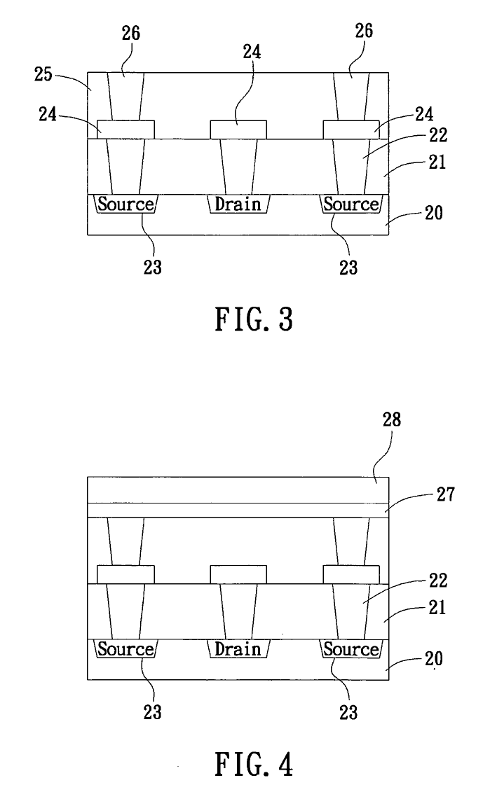

FIG. 3 is a cross-sectional diagram showing a second step of a method for manufacturing a resistance memory according to the present invention. In FIG. 3, a conducting layer 24 is formed on the first insulating layer 21 so that the conducting layer 24 is connected to the first plugs 22. Then, a second insulating layer 25 comprising a plurality of second plugs 26 is formed on the first insulating layer 21 and the conducting layer 24 so that the second plugs 26 are connected to the first plugs 22 through the conducting layer 24.

More particularly, a plurality of openings are formed in the second insulating layer 25 by photo-lithography and etching. A conductive material is deposited to fill in the plurality of openings and then the conductive material is planarized to form the plurality of second plugs 26. The conductive material is implemented by tungsten (W) or other conductive metal materials.

Please refer to FIG. 4, which is a cross-sectional diagram showing a third step of a method for manufacturing a resistance memory according to the present invention. In FIG. 4, an electrode layer 27 and a sacrificial layer 28 are sequentially formed on the second insulating layer 25. In the present embodiment, the electrode layer 27 is formed of one of Pt, Au, Pd, Ru, TiN, TiW, TiAlN and combination thereof, which are usually used for resistance memories and phase-change memories, by physical vapor-phase deposition (PVD) or chemical vapor-phase deposition (CVD). Moreover, the sacrificial layer 28 is formed of silicon dioxide (SiO₂) by physical vapor-phase deposition (PVD) or chemical vapor-phase deposition (CVD).

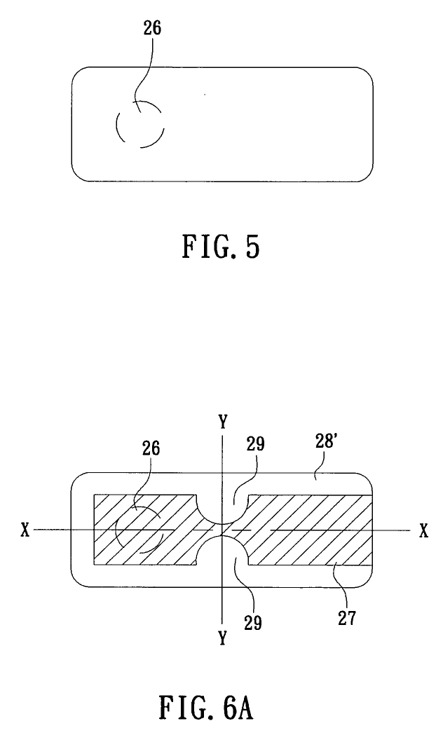

Since the planar dual-tip electrode structure of the present invention is symmetrical with respect to the drain, the following exemplifying cross-sectional diagrams only depict the left half with respect to the drain, as shown in FIG. 5. FIG. 5 is a top-view diagram of the left half of FIG. 4, wherein the region enclosed by the dotted line indicates the second plugs 26under the electrode layer and the sacrificial layer.

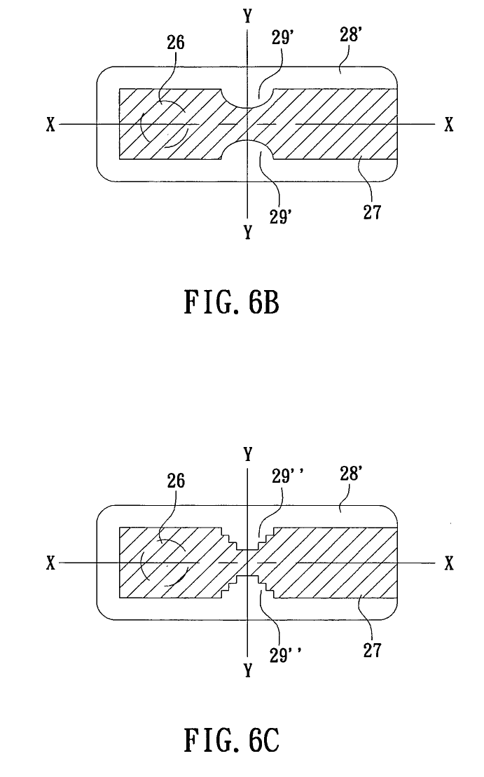

FIG. 6A is a cross-sectional diagram showing a fourth step of a method for manufacturing a resistance memory according to one embodiment of the present invention. In FIG. 6A, a patterned sacrificial layer 28′ is defined by photo-lithography and etching so that the patterned sacrificial layer 28′ comprises two adjacent head-to-head semi-circular patterns 29 to expose part of the electrode layer 27. Alternatively, the two adjacent head-to-head semi-circular patterns 29 can be replaced by two adjacent head-to-head semi-elliptic patterns 29′ (FIG. 6B) or semi-polygonal patterns 29″ (FIG. 6C). The two adjacent head-to-head semi-circular patterns 29 are symmetrical with respect to a dotted line XX and the centers of the two adjacent head-to-head semi-circular patterns 29 are connected by a dotted line YY, which is perpendicular to the dotted line XX.

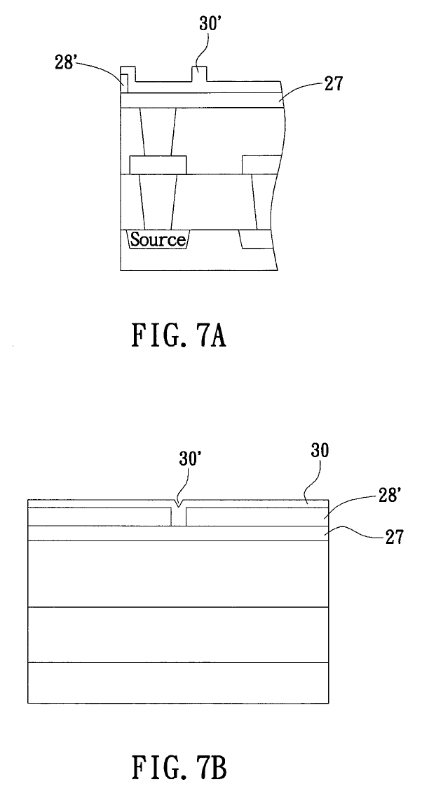

FIG. 7A and FIG. 7B are cross-sectional diagrams along the XX and YY directions respectively showing a fifth step of a method for manufacturing a resistance memory according to the present invention. In FIG. 7A and FIG. 7B, a thin film 30 formed of a material that the sacrificial layer 28 is formed of is deposited on the patterned sacrificial layer 28′ and the exposed part of the electrode layer 27. The thin film 30 is thick enough for the two adjacent head-to-head semi-circular patterns 29 to joint. In FIG. 7A and FIG. 7B, a protrusion 30′ in the thin film 30 is where the two adjacent head-to-head semi-circular patterns 29 joint.

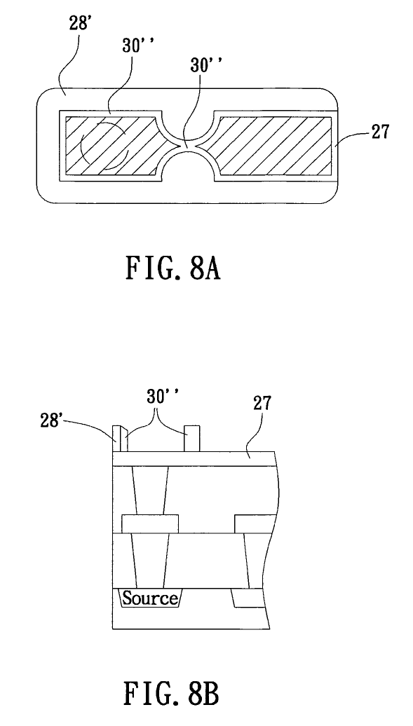

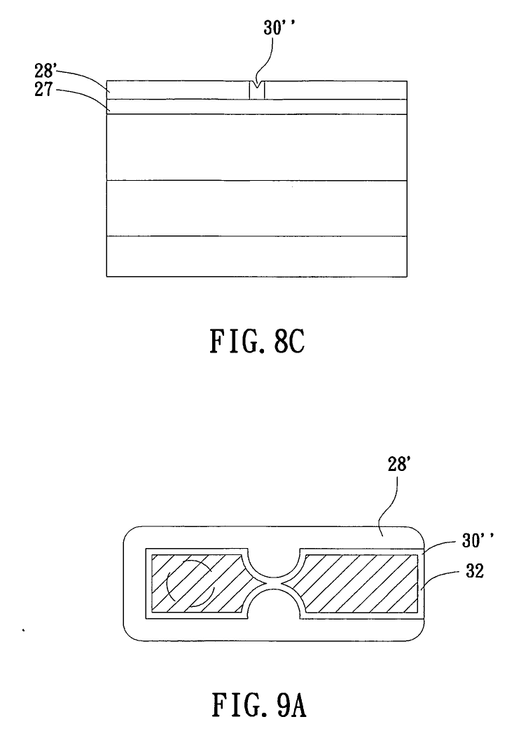

The thin film 30 is then anisotropically etched to form a sidewall 30″, as shown in FIG. 8A to FIG. 8C. FIG. 8A is a top-view diagram showing a sixth step of a method for manufacturing a resistance memory according to the present invention. FIG. 8B is a cross-sectional diagram along the XX direction showing a fifth step of a method for manufacturing a resistance memory according to the present invention. FIG. 8C is a cross-sectional diagram along the YY direction showing a fifth step of a method for manufacturing a resistance memory according to the present invention.

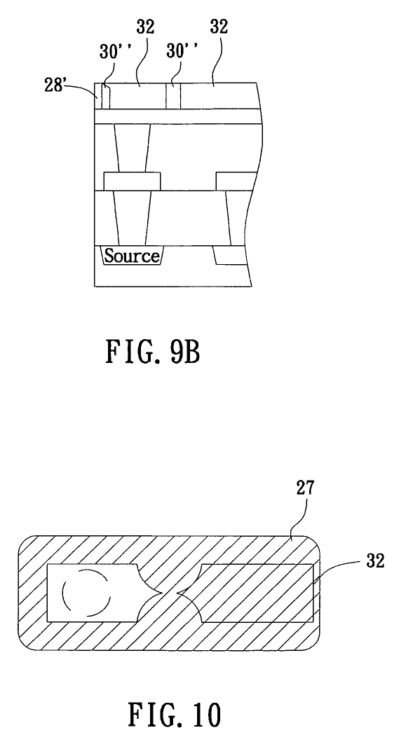

A mask layer 32 formed of another material different from the material that the sacrificial layer 28 is formed of is deposited to cover the exposed part of the electrode layer 27. The mask layer 32 is then planarized, as shown in FIG. 9A and FIG. 9B. FIG. 9A is a top-view diagram showing a seventh step of a method for manufacturing a resistance memory according to the present invention. FIG. 9B is a cross-sectional diagram along the XX direction showing a seventh step of a method for manufacturing a resistance memory according to the present invention. In the present embodiment, the mask layer 32 is formed of silicon nitride (Si₃N₄) by physical vapor-phase deposition (PVD) or chemical vapor-phase deposition (CVD).

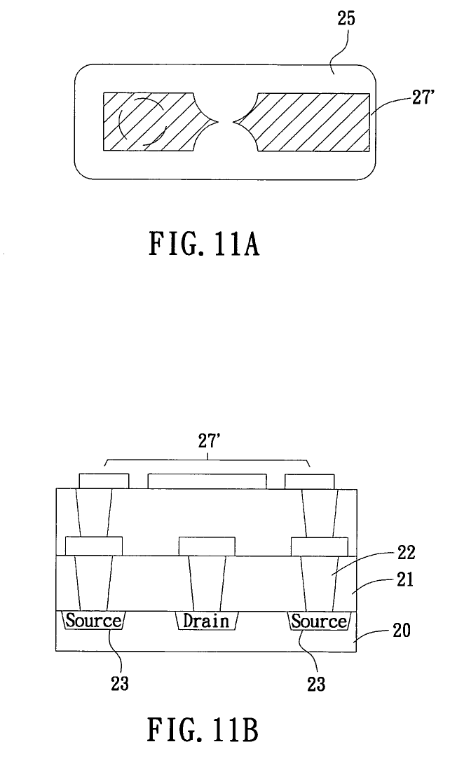

FIG. 10 is a top-view diagram showing an eighth step of a method for manufacturing a resistance memory according to the present invention. In FIG. 10, the patterned sacrificial layer 28″ and the sidewall 30″ are removed while remaining the mask layer 32 and exposing part of the electrode layer 27. The mask layer 32 is used to remove the exposed part of electrode layer 27 to expose part of the second insulating layer 25. Then, the mask layer 32 is removed to form a planar dual-tip electrode structure 27′, as shown in FIG. 11A and FIG. 11B, which depict a top-view diagram and a cross-sectional diagram, respectively, showing a ninth step of a method for manufacturing a resistance memory according to the present invention.

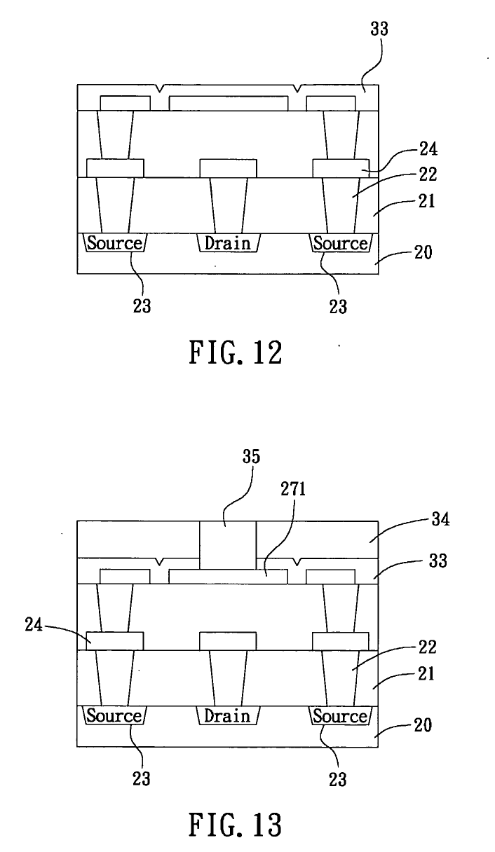

FIG. 12 is a cross-sectional diagram showing a tenth step of a method for manufacturing a resistance memory according to the present invention. In FIG. 12, a resistive conversion layer 33 is formed on the second insulating layer 25 to cover the planar dual-tip electrode structure 27′. In the present embodiment, the resistive conversion layer 33 is formed of an oxide used in general resistance memories such as HfO₂, Ta₂O₅, TiO₂, Nb₂O₅, Al₂O₃, CuO and a stack thereof or a phase-changing material such as GeSbTe (GST) by physical vapor-phase deposition (PVD) or chemical vapor-phase deposition (CVD).

At last, a third insulating layer 34 is formed on the resistive conversion layer 33 with a via 35 to connect a common top electrode of the planar dual-tip electrode structure 27′ to the ground (not shown), as shown in FIG. 13, which is a cross-sectional diagram showing an eleventh step of a method for manufacturing a resistance memory according to the present invention.

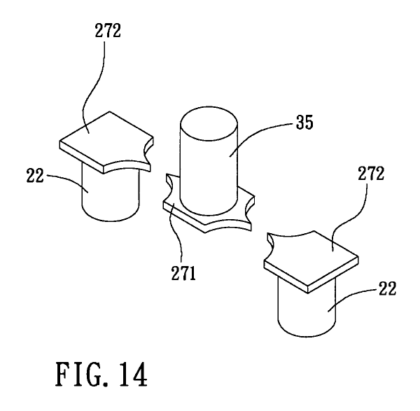

Therefore, a planar dual-tip electrode structure of a resistance memory as shown in FIG. 14 can be manufactured using the method for manufacturing a resistance memory as shown in FIG. 2 to FIG. 13. The planar dual-tip electrode structure comprises two memory cells each with a bottom electrode 272 and a common top electrode 271. The common top electrode 271 is connected to the ground through a via 35. The bottom electrodes 272 are connected to the source of a transistor through a plug 22, respectively. The bottom electrodes 272 and the common top electrode 271 are disposed on the same plane and are separated by a resistive conversion layer (not shown). By using such a structure, the current is confined between the electrode tips, as indicated by the dotted line in FIG. 14. Moreover, the method of the present invention is suitable for small-size devices because it is less affected by diffraction during exposure to cause distorted patterns.

According to the above discussion, it is apparent that the present invention discloses resistance memory is manufactured using semiconductor processing to comprise planar dual-tip electrodes so that the electric field in the resistance memory is concentrated to reduce the number of fuses in the dielectric material and improve the device characteristics. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What claimed are:

1. A method for manufacturing a resistance memory, comprising steps of:
providing a semiconductor substrate comprising a plurality of transistors, whereon a first insulating layer comprising a plurality of first plugs so that each of the plurality of first plugs are connected to the source/drain of one the plurality of transistors;
forming a conducting layer on the first insulating layer so that the conducting layer is connected to the first plugs;
forming a second insulating layer comprising a plurality of second plugs on the first insulating layer and the conducting layer so that the second plugs are connected to the first plugs through the conducting layer;
forming an electrode layer and a sacrificial layer sequentially on the second insulating layer;
defining a patterned sacrificial layer by photo-lithography and etching so that the patterned sacrificial layer comprises two adjacent head-to-head semi-circular, semi-elliptic or semi-polygonal patterns to expose part of the electrode layer;
depositing on the electrode layer a thin film formed of a material that the sacrificial layer is formed of, the thin film being thick enough for the two adjacent head-to-head semi-circular, semi-elliptic or semi-polygonal patterns to joint;
anisotropically etching the thin film to form a sidewall;
depositing on the electrode layer a mask layer formed of another material different from the material that the sacrificial layer is formed of and planarizing the mask layer;
removing the patterned sacrificial layer and the sidewall while remaining the mask layer and exposing part of the electrode layer;
using the mask layer to remove the exposed part of electrode layer to expose part of the second insulating layer and removing the mask layer to form a planar dual-tip electrode structure;
forming a resistive conversion layer on the second insulating layer to cover the planar dual-tip electrode structure; and
forming a third insulating layer on the resistive conversion layer with a via to connect a common top electrode of the planar dual-tip electrode structure to the ground.

2. The method for manufacturing a resistance memory as recited in claim 1, wherein the step for forming the plurality of first plugs comprises:
forming a plurality of openings in the first insulating layer by photo-lithography and etching; and
depositing a conductive material to fill in the plurality of openings and planarizing the conductive material.

3. The method for manufacturing a resistance memory as recited in claim 2, wherein the conductive material is tungsten.

4. The method for manufacturing a resistance memory as recited in claim 1, wherein the step for forming the plurality of second plugs comprises:
forming a plurality of openings in the second insulating layer by photo-lithography and etching; and
depositing a conductive material to fill in the plurality of openings and planarizing the conductive material.

5. The method for manufacturing a resistance memory as recited in claim 4, wherein the conductive material is tungsten (W).

6. The method for manufacturing a resistance memory as recited in claim 1, wherein the electrode layer is formed of one of Pt, Au, Pd, Ru, TiN, TiW, TiAlN and combination thereof.

7. The method for manufacturing a resistance memory as recited in claim 6, wherein the electrode layer is formed by physical vapor-phase deposition (PVD) or chemical vapor-phase deposition (CVD).

8. The method for manufacturing a resistance memory as recited in claim 1, wherein the sacrificial layer is formed of silicon dioxide (SiO₂).

9. The method for manufacturing a resistance memory as recited in claim 8, wherein the sacrificial layer is formed by physical vapor-phase deposition (PVD) or chemical vapor-phase deposition (CVD).

10. The method for manufacturing a resistance memory as recited in claim 1, wherein the mask layer is formed of silicon nitride (Si₃N₄).

11. The method for manufacturing a resistance memory as recited in claim 10, wherein the mask layer is formed by physical vapor-phase deposition (PVD) or chemical vapor-phase deposition (CVD).

12. The method for manufacturing a resistance memory as recited in claim 1, wherein the resistive conversion layer is formed of one of HfO₂, Ta₂O₅, TiO₂, Nb₂O₅, Al₂O₃, CuO, a stack thereof and GeSbTe (GST).

13. The method for manufacturing a resistance memory as recited in claim 12, wherein the resistive conversion layer is formed by physical vapor-phase deposition (PVD) or chemical vapor-phase deposition (CVD).

14. A resistance memory with a planar dual-tip electrode structure comprising:
a first memory cell comprising a first bottom electrode and a common top electrode; and
a second memory cell including a second bottom electrode and the common top electrode shared with the first memory cell;
wherein the first bottom electrode, the second bottom electrode and the common top electrode are disposed on the same plane and are separated by a resistive conversion layer.

15. The resistance memory as recited in claim 14, wherein the common top electrode is connected to the ground through a via.

16. The resistance memory as recited in claim 14, wherein the first bottom electrode and the second bottom electrode are connected to the source of a transistor through a plug, respectively.

17. The resistance memory as recited in claim 14, wherein the resistive conversion layer is formed of one of HfO₂, Ta₂O₅, TiO₂, Nb₂O₅, Al₂O₃, CuO, a stack thereof and GeSbTe (GST).

18. The resistance memory as recited in claim 17, wherein the resistive conversion layer is formed by physical vapor-phase deposition (PVD) or chemical vapor-phase deposition (CVD).

19. The resistance memory as recited in claim 14, wherein the first bottom electrode, the second bottom electrode and the common top electrode are formed of one of Pt, Au, Pd, Ru, TiN, TiW, TiAlN and combination thereof.

20. The resistance memory as recited in claim 19, wherein the first bottom electrode, the second bottom electrode and the common top electrode are formed by physical vapor-phase deposition (PVD) or chemical vapor-phase deposition (CVD).
